(19) United States
(12) Patent Application Publication
(10) Pub. No.: US 2003/0058902 A1
(43) Pub. Date: Mar. 27, 2003

(54) Method for improving thermal efficiency of a semiconductor laser

(76) Inventor: Wupen Yuen, Palo Alto, CA (US)

Correspondence Address: HELLER EHRMAN WHITE & MCAULIFFE LLP, 275 MIDDLEFIELD ROAD, MENLO PARK, CA, 94025-3506, US

(21) Appl. No.: 10/259,196

(22) Filed: Sep. 27, 2002

Related U.S. Application Data
(60) Provisional application No. 60/325,896, filed on Sep. 27, 2001.

(51) Int. Cl. H01S 3/08; H01S 5/00; H01S 3/10

(52) U.S. Cl. 372/20; 372/96; 372/45

(57) ABSTRACT

A tunable laser has an electrically responsive substrate. A support block is positioned on the electrically responsive substrate. A structure includes a base section resting on the support block. A deformable section extends above the electrically responsive substrate and creates an air gap between the deformable section and the electrically responsive substrate. An active head is positioned at a predetermined location on the deformable section and is at least a portion of the top reflector member. An electrical tuning contact is disposed on the structure to apply a tuning voltage, V in order to produce a vertical electrostatic force Fd between the electrical tuning contact and the electrically responsive substrate. This alters the size and the shape of the air gap and tuning the tunable laser. At least one heat spreader layer is disposed within the electrically responsive substrate.

### CROSS-REFERENCE TO RELATED APPLICATIONS

This application claims the benefit of U.S. Serial No. 60/325,896, filed Sep. 27, 2001, which application is fully incorporated herein by reference.

### BACKGROUND OF THE INVENTION

1. Field of the Invention

The present invention relates generally to semiconductor lasers, and more particularly to reducing the temperature increase in tunable Vertical Cavity Surface Emitting Lasers (VCSELs).

2. Description of Related Art

Optical communication systems are a substantial and fast growing constituent of communications networks. Such optical systems include, but are not limited to, telecommunication systems, cable television systems, and Local Area Networks (LANs). Optical systems are described in Gowar, Ed. Optical Communication Systems, (Prentice Hall, N.Y.) c. 1993, the disclosure of which is incorporated herein by reference. Currently, the majority of optical systems are configured to carry an optical channel of a single wavelength over one or more optical wave-guides such as fibers.

To convey the information form plural sources, time division multiplexing (TDM) is frequently employed. In TDM, a particular time slot is assigned to each information source, the complete signal being constructed from the signal collected from each time slot. While this is a useful technique for carrying plural information sources on a s single channel, its capacity is limited by fiber dispersion and the need to generate high peak power pulses.

While the need for communication systems bandwidth increases, the current capacity of existing wave-guiding media is limited. Although capacity may be expanded, e.g. by laying more fiber optic cables, the cost of such expansion is prohibitive. Consequently, there exists a need for a cost-effective way to increase the capacity of the existing optical wave-guides.

Wavelength division multiplexing (WDM) and dense wavelength division multiplexing (DWDM) have been explored as approaches for increasing the capacity of the existing fiber optic networks. Such system employs plural optical signal channels, each channel being assigned a particular channel wavelength. In a typical system, optical signal channels are generated, multiplexed to form an optical signal comprised of the individual optical signal channels, transmitted over a single wave-guide, and de-multiplexed such that each channel wavelength is individually routed to a designated receiver. Through the use of optical amplifiers, such as doped fiber amplifiers, plural optical channels are directly amplified simultaneously, facilitating the use of WDM and DWDM approaches in long distance optical systems.

Crucial to providing sufficient bandwidth for WDM and DWDM, while at the same time avoiding bottlenecks, is the ability to assign and reassign wavelengths as needed throughout the network and providing the bandwidth when and where needed. Allowing more flexibility in the way fiber capacity is provisioned is the driving force behind the requirements of next generation optical networks. Future network capacity needs will probably require a multi fold scalability beyond a network's initial installed capacity and also a rapid service activation to allow high capacity links to be deployed as needed.

Tunable lasers that can be tuned over a wide range of wavelengths and switched at nanosecond speeds best meet such requirements. A number of schemes have been proposed and studied to obtain frequency tuning of semiconductor lasers. These methods have typically relied on tuning the index of refraction of the optical cavity.

In addition, the bulk of the tuning schemes have been attempted with edge emitting laser structures. Unlike vertical cavity surface emitting lasers (VCSEL), these structures are not single mode and consequently the use of distributed Bragg reflectors or distributed feedback, both of which are difficult to fabricate, are required to select a single mode.

Interferometric techniques that rely on variable selection of different Fabry-Perot modes for tuning from a comb of modes have also been proposed. Among these are asymmetric y-branch couplers and vertical cavity filters. These methods produce tuning ranges of up to 100 nm, but are, however, restricted to discrete tuning only and are potentially unstable between the tuning steps.

Most of the above mentioned techniques are polarization sensitive and therefore cannot be readily adopted to optical communications systems, which need to be robust and inexpensive and consequently insensitive to beam polarization.

In case of semiconductor lasers there are two types of devices according to the direction in which the light output is generated: edge emitting and vertically emitting. Vertical emitting devices have many advantages over edge emitting devices, including the possibility of wafer scale integration and testing, and the possibility of forming two dimensional arrays of the vertically emitting devices. Moreover, the circular nature of the light output beam from these devices makes them ideally suited for coupling into optical fibers for use in optical interconnects or other optical systems.

A critical and costly problem in all WDM and DWDM is created by the need for exact wavelength registration between transmitters and receivers. A tunable receiver capable of locking to the incoming signal over a range of wavelengths variation would relax the extremely stringent wavelength registration problem. The tunability requirement can best be met by proper VCSEL utilization. VCSELs possess desirable qualities for telecommunications: circular mode profile that makes them ideally suited for coupling into optical fibers, single mode operation, surface mode operation and compact size. Complete description of the VCSEL device and its operation can be found in the U.S. issued patent numbers: U.S. Pat. Nos. 5,629,951 and 5,771,253 both of which are incorporated herein by reference.

The advances in communication technologies described above depend greatly on high quality stable laser sources. Greater precision made possible with these devices increases the number of wavelength channels per optical fiber, as inter-channel interference can be prevented with less space between wavelengths. Consequently, the speed of a transmitting system is increased proportionately to the number of individual channels. A key requirement to maintaining these advantages is the stability of laser performance.

The performance of many electrical devices is adversely affected by the heat generated during the normal device operation. This is true of many semiconductor devices as the reverse leakage currents increase and adversely affect the device performance. The semiconductor lasers are particularly sensitive to temperature changes. Moreover, obtaining necessary laser output power and speed has become far more difficult as the system requirements call for longer wavelength lasers, typically in the 1550 nanometer (nm) range. In order to achieve needed light output, current driven through the lasing aperture area of the laser has to be increased. The situation is worsened further at longer wavelengths since non-radiative recombination coefficient is directly proportional to the wavelength, consequently, a greater portion of the injected current is diverted to the non radiative mechanisms and, therefore, the amount of injected current available for lasing is proportionately reduced.

These losses call for increased input current, and, as a result of this, the current densities in the current injection area reach magnitudes on the order of several thousand amperes per square centimeter. Such high current densities cause the device temperature to increase further. The temperature increases causes further losses in laser power output and its speed. The device wavelength also shifts and drive current needs to be increased further to obtain desired performance.

Different methods have been developed to address the problems caused by temperature increase, each method having its own shortfalls. One approach utilizes reduced resistivity active layers. This, however, causes the laser threshold current to increase, which in turn calls for a higher drive current. Moreover, the approach only improves device power down to certain values of resistivity and beyond that the power drops off again. Similarly, changing the strain in laser quantum well structure only produces a limited success. The device power improves up to certain values of strain and decreases rapidly beyond those values.

Better mechanical heat sinking and Peltier element cooling have also been utilized to reduce the device temperature. While it is possible to adequately cool the device using Peltier element, the disadvantages are numerous: high current consumption, additional heat generation, possible overheating, the size of the cooling set-up and increased costs. In other words, there are no suitable ways to reduce the device temperature absent complicated and costly cooling arrangements.

In other words, there are no suitable ways to reduce the device temperature absent complicated and costly cooling arrangements. For these reasons there is a need to develop a structure that better handles longer wavelength and increased power requirements, stabilizes the device operation and reduces the demand on external cooling method employed. The addition of the heat dissipating layer disclosed herein meets such need.

### SUMMARY OF THE INVENTION

Accordingly, an object of the present invention to provide an apparatus for tuning the resonance wavelength of a Fabry-Perot cavity in a continuous manner over a wide range of wavelengths.

Another object of the present invention to provide a vertical cavity apparatus with cantilever arm for tuning the resonance wavelength of a Fabry-Perot cavity in a continuous manner over a wide range of wavelengths.

Yet another object of the present invention to reduce the laser temperature by conducting the heat away from the laser aperture area by implementing a heat dissipating layer.

Still another object of the present invention is to increase the device power and speed.

Another object of the invention to reduce the demand on the external cooling arrangement needed to maintain the device temperature within the specified range.

A further object of the invention is that the device may be grown in one processing step.

Still a further object of the present invention that the apparatus is polarization insensitive.

Yet another object of the present invention to ensure that the apparatus be simple in construction, easy to control and straightforward to manufacture.

These and other objects of the present invention are achieved in a tunable laser with an electrically responsive substrate. A support block is positioned on the electrically responsive substrate. A structure includes a base section resting on the support block. A deformable section extends above the electrically responsive substrate and creates an air gap between the deformable section and the electrically responsive substrate. An active head is positioned at a predetermined location on the deformable section and is at least a portion of the top reflector member. An electrical tuning contact is disposed on the structure to apply a tuning voltage, V in order to produce a vertical electrostatic force Fd between the electrical tuning contact and the electrically responsive substrate. This alters the size and the shape of the air gap and tuning the tunable laser. At least one heat spreader layer is disposed within the electrically responsive substrate.

In another embodiment of the present invention, a method is provided for reducing temperature in a device employed for tuning a resonance wavelength of a Fabry-Perot cavity. The cavity is a structure with a base section, a deformable section, an active head, a heat spreader layer, a bottom reflecting and top reflector member. A support block is positioned on an electrically responsive substrate containing the Fabry-Perot cavity. The structure on the support block is produced such that the active head contains at least a portion of the top reflector member and is positioned above the Fabry-Perot cavity. The deformable section extends above the electrically responsive substrate and creates an air gap between the deformable section and the electrically responsive substrate. An electrical tuning contact is disposed on the cantilever structure. A tuning voltage is applied to produce a vertical electrostatic force Fd between the electrically responsive substrate in order to alter the size of the air gap and tuning the resonant wavelength.

### BRIEF DESCRIPTION OF THE DRAWINGS

FIG. 1 is a side view of one embodiment of a vertical optical cavity apparatus of the present invention.

FIG. 2 is a diagram that illustrates thermal resistance of the apparatus with and without a heat spreading layer.

FIG. 3 is a diagram that illustrates temperature change of the FIG. 1 apparatus with and without the heat spreading layer as a function of drive current.

FIG. 4 is a diagram that illustrates output power of the FIG. 1 apparatus with and without the heat spreading layer

FIG. 5(a) is a diagram that illustrates the effect of temperature increase on the laser threshold current.

FIG. 5(b) is a diagram of one embodiment of the present invention.

FIG. 6 is a diagram that illustrates the effect of temperature increase on the wavelength.

### DETAILED DESCRIPTION OF THE PREFERRED EMBODIMENT

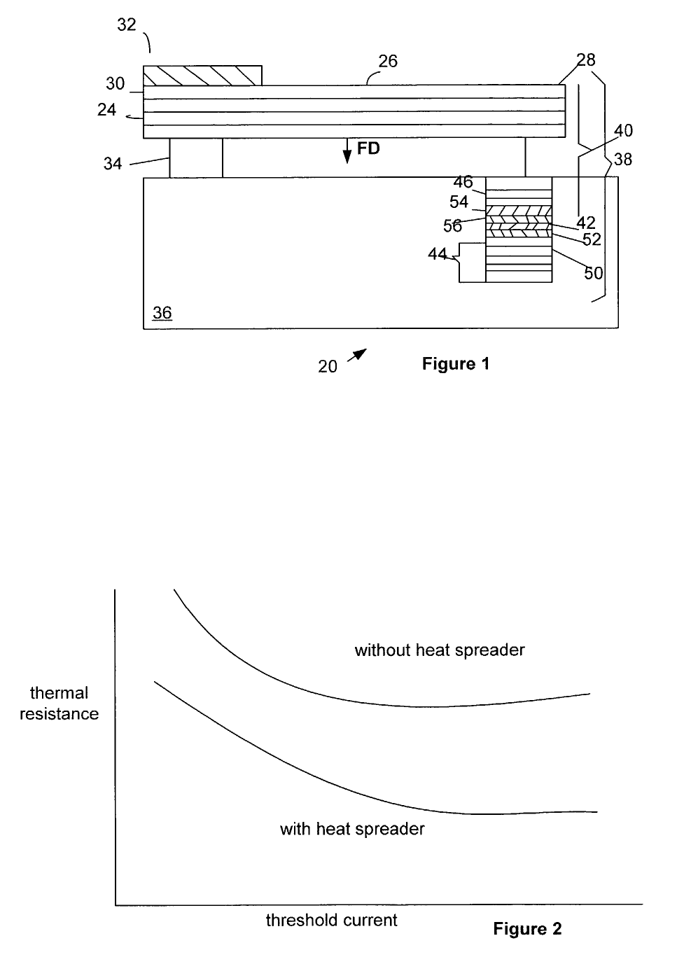

In one embodiment of the present invention, a cantilever arm apparatus uses an electrostatic force pulling on a cantilever arm. The mechanical deflection resulting from this force can be used to change the length of the Fabry-Perot microcavity and consequently to tune the resonant wavelength. FIG. 1 shows a side view of a simple embodiment of such an apparatus. If desired the device can be made to operate at a fixed wavelength.

Referring now to FIG. 1, a cantilever arm apparatus 20 has a cantilever structure 22 consisting of a base 24, a cantilever arm 26, and active head 28. In the embodiment shown, the bulk of cantilever arm structure 22 consists of four reflective layers 30, which form a distributed Bragg reflector (DBR). It is preferable to make layers 30 of AlGaAs. Different compositional ratios are used for individual layers 30, e.g., Al(0.09)Ga(0.91)As/Al(0.58) Ga(0.42)As. The topmost layer 30 is heavily doped to ensure good contact with an electrical tuning contact 32 deposited on top of cantilever structure 22.

The actual number of layers 30 varies from 1-20 depending on the desired reflectivity of DBR 30. Furthermore, any suitable reflective material other than AlGaAs may be used to produce the reflective layers 30. A person skilled in the art will be able to choose the right materials and dimensional parameters for the reflective layers 30. Finally, it is not even necessary that the cantilever arm 26 or the base 24 be made of reflective layers as long as the active head 28 includes the reflective layers 30.

In the embodiment shown, base 24 is rectangular and suitably large to ensure dimensional stability of the cantilever structure 22. The width of the cantilever arm 26 ranges typically from 5 to 10 microns while the length is 100 to 500 microns or more. The cantilever arm stiffness increases as the length decreases. Consequently, a shorter cantilever arm requires greater forces to deform but the shorter cantilever arm also resonates at a higher frequency. The preferred diameter of the active head 28 falls between 10 and 40 microns. Of course, the other dimensions are also possible and a person skilled in the art will be able to compute them according to the requirements at hand.

Electrical tuning contact 32 may reside on top of cantilever arm structure 22 or may be suitably placed elsewhere on the cantilever arm 22 or elsewhere on the device. Where contact 32 resides on top of arm 22, it may cover a portion or all of arm 22. In this embodiment, electrical tuning contact 32 is made of gold. However, any other electrically conducting material can be used. The only limitation is that the electrical tuning contact 32 be sufficiently large to allow application of the tuning voltage V as discussed below.

Base 24 rests on a support block 34 across which a voltage can be sustained. In this case, block 34 is composed of GaAs or InP. Block 34 sits on an electrically responsive substrate 36, preferably made of suitably doped GaAs or InP. A voltage difference between layers 30 and substrate 36 causes a deflection of arm 26 towards substrate 36. If layers 30 and substrate 36 are opposite doped, then a reverse bias voltage can be established between them. Substrate 36 is sufficiently thick to provide mechanical stability to entire cantilever arm apparatus 20. Inside substrate 36 and directly under active head 28 are lodged one or more sets of reflective layers 30 forming a second DBR.

A Fabry-Perot cavity 38 is formed by a top reflector 40, an active region or medium 52, a conventional cavity spacer layer 42, and a bottom reflector 44. Top reflector 40 is formed by DBR layers 30, an air gap 48, which acts as a DBR layer, and a second set of reflective layers 46 in the substrate 36. In other words, top reflector 40 is composed of two semiconductor portions sandwiching tunable air gap 48. The first semiconductor portion is contained in active head 28 in the layers 32. The second semiconductor portion, consisting of layers 46, is lodged inside substrate 36.

Bottom reflector 44 is composed of four reflecting layers 50. Just as in the case of layers 30, the number of layers 50 will depend on the desired reflectivity of bottom reflector 44. If, as in a filter, no active region or spacer layer is required, the top reflector may be composed of only top DBR layers 30. In this case, air gap 48 may itself form the spacer layer, and the bottom reflector is formed by layers 50.

In a Fabry-Perot cavity such as cavity 38, the total number of layers similar to layers 44 can vary from none to several tens. If no active layer is needed, tunable air gap 48 can itself form the spacer layer and the top reflector can be entirely formed from layers 30 lodged in active head 28. However, where an active layer is required, such as in laser or in detector, tunable air gap 48 and the cavity spacer layer such as layer 42 may be distinct and independent. In this case, at least one layer 46 is required.

The actual number of layers 46 depends on the number of layers 30, the desired reflectivity, the desired tuning range, and other well-known optical parameters of the apparatus. However, in any cantilever arm apparatus similar to apparatus 20, active head 28 has to contain at least one layer 30. The size of the active head 28 can be tailored to suit the specific device requirements. Additionally, the current confinement and the lasing aperture defining layer 54 may be employed in laser applications. The layer 54 is comprised of group III-V material and another readily oxidizable element, preferably aluminum. Alternatively, the layer 54 function may be accomplished by an ion implantation or a similar process. The heat spreader layer 56 reduces the device temperature by conducting the heat away form the high current density area of the aperture defining layer 54. This results into the accumulated heat being spread more uniformly throughout device 20 and towards heat sink 60. The layer 56 can be amorphous material or semiconducting compound from group III-V materials, preferably GaAs, InP or other materials of suitable thermal conductivity and it may be lattice matched or lattice mismatched to the active region 52.

The layer 56 may be positioned anywhere in substrate 36, or on the top or the bottom of substrate 36, but preferably as close to the active region 52 as possible. These and other objects of the present invention are achieved in a tunable laser with an electrically responsive substrate. A support block is positioned on the electrically responsive substrate. A structure includes a base section resting on the support block. A deformable section extends above the electrically responsive substrate and creates an air gap between the deformable section and the electrically responsive substrate. An active head is positioned at a predetermined location on the deformable section and is at least a portion of the top reflector member.

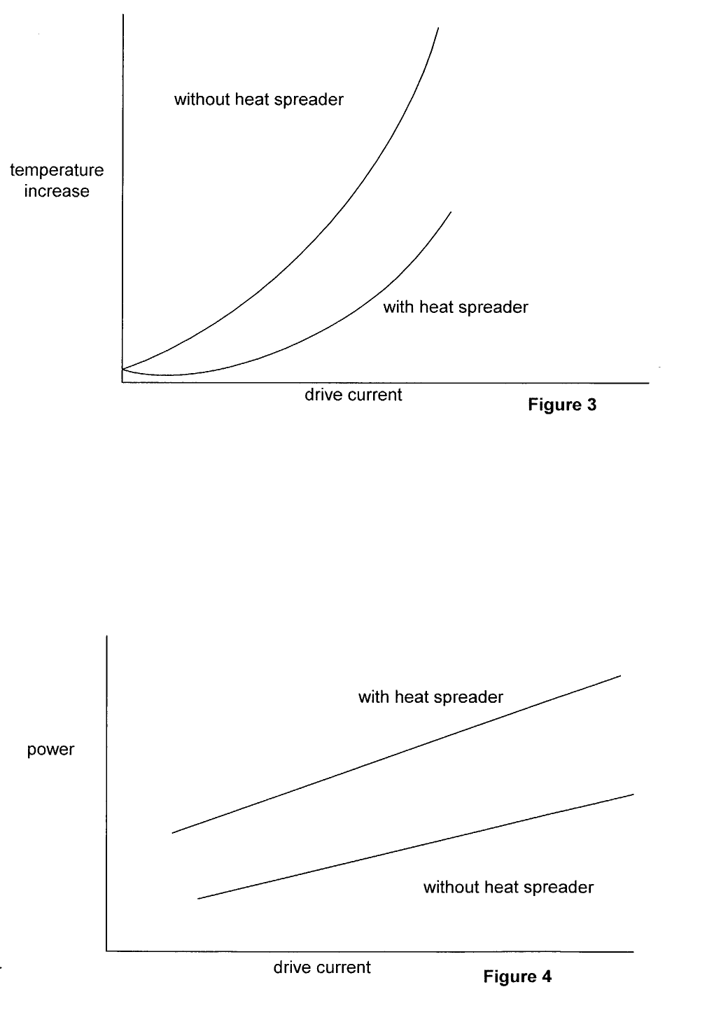

An electrical tuning contact is disposed on the structure to apply a tuning voltage, V in order to produce a vertical electrostatic force Fd between the electrical tuning contact and the electrically responsive substrate. This alters the size and the shape of the air gap and tuning the tunable laser. At least one heat spreader layer is disposed within the electrically responsive substrate. FIG. 2 illustrates the thermal resistance of apparatus 20 with and without heat spreading layer 56. FIG. 3 illustrates temperature change of the apparatus 20 with and without heat spreading layer 56 as a function of drive current. FIG. 4 illustrates output power of apparatus 20 with and without heat spreading layer 56.

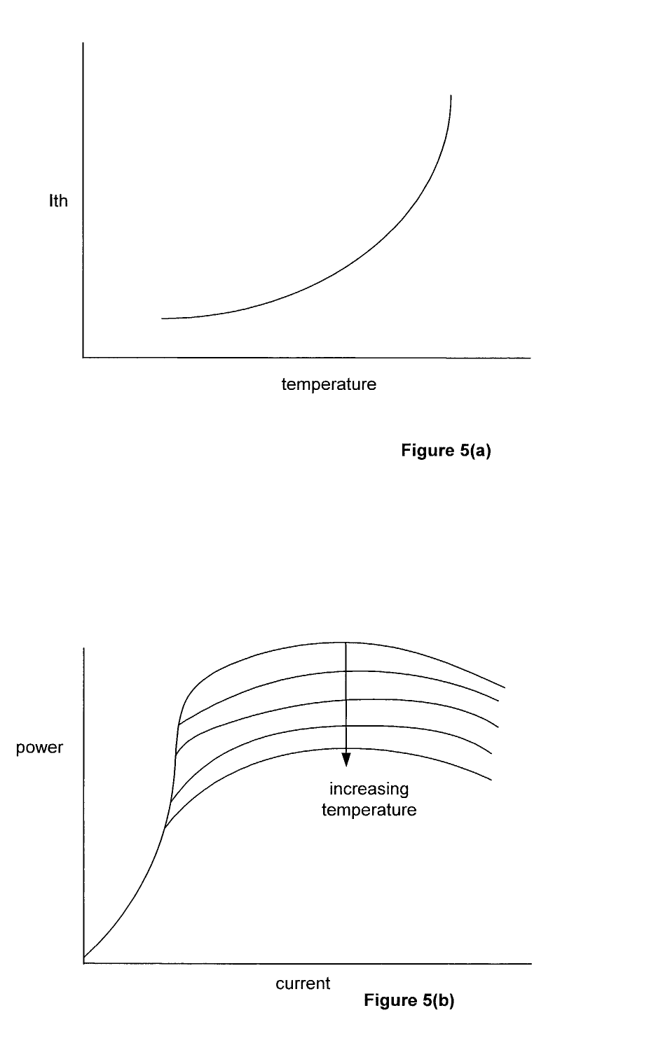

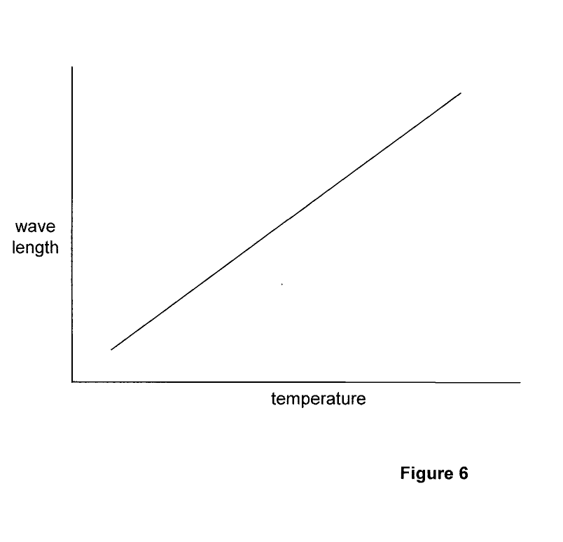

FIG. 5(a) shows the temperature dependence of the laser threshold current of apparatus 20 for temperatures between approximately 20 and 50 degrees Celsius. FIG. 5(b) illustrates the effects of current and power relative to increasing the temperature. FIG. 6 illustrates a typical change in the laser emission wavelength as a function of temperature. These changes adversely affect performance of a system employing lasers that are set to operate at specific power level and specific wavelength.

Referring again to FIG. 1, heat layer 56 is positioned right below aperture defining layer 54, but it may also be positioned right on top of layer 54. Multiple layers 56 may also be utilized. Preferably, the thermal conductivity of layer 56 is higher than that of the intrinsic material of the same type.

The remaining part of Fabry-Perot cavity 38 consists of a conventional cavity spacer 42, active medium 52, and four reflecting layers 50. The latter constitute bottom reflector 44. Just as in the case of layers 30 and 46, the number of layers 50 will vary depending on the desired reflectivity of bottom reflector 44.

The height of block 34 is typically 2.5 micrometers; thus the cantilever arm structure 22 is situated distance D=2.5 micrometers above substrate 36. Of course, block 34 can be placed significantly higher or lower, depending on the desired tuning range.

To tune the Fabry-Perot cavity 38, tuning voltage V is applied to a tuning contact 32. The application of tuning voltage V results in charge accumulation on contact 32 and the bridge structure 22. The charge on contact 32 and structure 22 causes an equal and opposite charge to accumulate at the surface of electrically responsive substrate 36. The attracting charges produce a vertical force Fd acting on the bridge arm 26 and the active head 28. Vertical force Fd causes the bridge arm 26 to deform and distance D to decrease.

As distance D decreases so does the effective length of Fabry-Perot cavity 38. A change in the cavity length alters the resonance wavelength of the cavity. Thus, decreasing distance D results in decease in the resonance wavelength of the Fabry-Perot micro cavity. Furthermore since distance D is a continuous function of tuning voltage V, and since V can be adjusted continuously, the tuning of the wavelength is continuous. Because active head 28 is nearly circularly symmetric, the bridge arm apparatus 20 is polarization-insensitive and thus well suited for applications in optical communications systems. Apparatus 20 is also simple in construction, easy to control and may be manufactured in one processing step.

While the invention has been described in connection with what is presently considered to be the most practical and preferred embodiment, it is to be understood that the invention is not limited to the disclosed embodiment, but on the contrary it is intended to cover various modifications and equivalent arrangement included within the spirit and scope of the claims which follow.

What is claimed is:

1. A tunable laser comprising:
an electrically responsive substrate;
a support block positioned on the electrically responsive substrate;
a structure including a base section resting on the support block,
a deformable section extending above the electrically responsive substrate and creating an air gap between the deformable section and the electrically responsive substrate, and an active head positioned at a predetermined location on the deformable section comprising at least a portion of a top reflector member;
an electrical tuning contact disposed on the structure for applying a tuning voltage, V, to produce a vertical electrostatic force Fd between the electrical tuning contact and the electrically responsive substrate, thereby altering the size and the shape of the air gap and tuning the tunable laser; and
at least one heat spreader layer disposed within the electrically responsive substrate.

2. The device of claim 1 wherein the deformable section is a cantilever structure.

3. The device of claim 2 wherein the cantilever structure is a cantilever arm and the active head is located at the free end of the arm.

4. The device of claim 1 wherein the electrically responsive substrate is doped with a positive charge carrier and the electrical tuning contact is doped with a negative charge carrier, thereby producing a pn-junction between the electrically responsive substrate and the electrical tuning contact.

5. The device of claim 1 wherein the electrically responsive substrate is doped with a negative charge carrier and the electrical tuning contact is doped with a positive charge carrier, thereby producing a pn-junction between the electrically responsive substrate and the electrical tuning contact

6. The device of claim 1 wherein the laser is a vertical cavity surface emitting laser further comprising an active region, a current confinement and a laser aperture defining layer.

7. The device of claim 1 wherein the at least one heat spreader layer is positioned anywhere between the top and the bottom surface of the electrically responsive substrate.

8. The device of claim 1 wherein the at least one heat spreader layer is positioned on top of the electrically responsive substrate.

9. The device of claim 1 wherein the at least one heat spreader layer is positioned on the bottom of the electrically responsive substrate.

10. The device of claim 6 wherein the at least one heat spreader layer is positioned adjacent to the active region.

11. The device of claim 6 wherein the at least one heat spreader layer is positioned immediately above of the current confinement and laser aperture defining layer.

12. The device of claim 6 wherein the at least one heat spreader layer is positioned immediately below the current confinement and laser aperture defining layer.

13. The device of claim 6 wherein the at least one heat spreader layer is amorphous material.

14. The device of claim 6 wherein the at least one heat spreader layer is semiconducting compound comprising III-V group elements.

15. The device of claim 6 wherein the at least one heat spreader layer is lattice matched to the active region.

16. The device of claim 6 wherein the at least one heat spreader layer is not lattice matched to the electrically responsive substrate.

17. The device of claim 1 wherein the thermal conductivity of the at least one heat spreading layer is greater than the same type intrinsic material.

18. Method for reducing temperature in a The device employed for tuning a resonance wavelength of a Fabry-Perot cavity using a structure comprising a base section, a deform able section, an active head, a heat spreader layer, a bottom reflecting and top reflecting member, the method comprising the steps of:
positioning a support block on an electrically responsive substrate containing the Fabry-Perot cavity;
producing the structure on the support block such that the active head contains at least a portion of the top reflecting means and is positioned above the Fabry-Perot cavity, and the deformable section extends above the electrically responsive substrate and creates an air gap between the deformable section and the electrically responsive substrate;
disposing an electrical tuning contact on the cantilever structure;
applying a tuning voltage to produce vertical electrostatic force Fd between the electrically responsive substrate, thereby altering the size of the air gap and tuning the resonant wavelength.

19. The method of claim 18 wherein the structure is a cantilever structure;

20. The method of claim 18 wherein the Fabry-Perot cavity is used as a lasing cavity.

21. The method of claim 18 wherein the Fabry-Perot is used as a vertical cavity surface emitting lasing cavity.
